(19) United States
(12) Patent Application Publication
(10) Pub. No.: US 2007/0096766 A1
(43) Pub. Date: May 3, 2007

(54) CHOPPER TYPE COMPARATOR

(75) Inventor: Hidemitsu Baba, Gunma-ken (JP)

Correspondence Address: WATCHSTONE P + D, 1250 CONNECTICUT AVENUE, N.W., SUITE 700, WASHINGTON, DC, 20036, US

(73) Assignee: Sanyo Electric Co., Ltd., Osaka (JP)

(21) Appl. No.: 11/277,741

(22) Filed: Mar. 28, 2006

(30) Foreign Application Priority Data
Mar. 28, 2005 (JP) JP2005-092868

(51) Int. Cl. G01R 31/26

(52) U.S. Cl. 324/768

(57) ABSTRACT

In some examples, a chopper type comparator for comparing an analog voltage to be measured and a reference voltage by sampling and outputting an “H” level signal or an “L” level signal depending on the comparison result includes a capacitor configured to store a potential difference between the analog voltage and the reference voltage, and an inverter configured to receive an output signal from the capacitor. The inverter includes a first p-channel transistor with a threshold voltage lower than a normal threshold voltage, a second p-channel transistor with a normal threshold voltage, a first n-channel transistor with a normal threshold voltage, and a second n-channel transistor with a threshold voltage lower than a normal threshold voltage. The second p-channel transistor is turned off by a standby signal and the first n-channel transistor is turned off by an inversion signal of the standby signal to thereby decrease leakage current of the inverter in a standby mode.

This application claims priority under 35 U.S.C. §119 to Japanese Patent Application No. 2005-092868 filed on Mar. 28, 2005, the entire disclosure of which is incorporated herein by reference in its entirety.

### BACKGROUND OF THE INVENTION

1. Field of the Invention

The present invention relates to, inter alia, a chopper type comparator, and some preferred embodiments relate to a chopper type comparator for use in, e.g., a successive approximation type A/D converter.

2. Description of the Related Art

The following description sets forth the inventor's knowledge of related art and problems therein and should not be construed as an admission of knowledge in the prior art.

In an 8 bits successive approximation type A/D converter, conventionally known is an A/D conversion type converter which realizes a 2 to the 8^{th} power resolution by 8 times of comparison operations. FIG. 1 shows a typical conventional successive approximation type A/D converter including a chopper type comparator 1, an 8 bits DAC (Digital Analog Converter) 2, and a successive approximation logical circuit 3.

In the above-mentioned A/D converter, the chopper type comparator 1 is configured to sample and hold an analog input voltage (AIN) inputted from an outside. The sample-held AIN is compared with a DAC output from the 8 bits DAC 2 by the chopper type comparator 1, and the comparison result is outputted to the successive approximation logical circuit 3 as a result (signal). In the 8 bits DAC 2, the digital values are obtained from the 8 bits MSB side.

By executing the aforementioned comparisons eight times, the AIN can be converted into a digital value. The successive approximation logical circuit 3 outputs the digitalized value as a DOUT.

A conventional common chopper type comparator for use in the successive approximation A/D converter shown in FIG. 1 is shown in FIG. 4. In FIG. 4, TG1, TG2, TG3, and TG4 each denotes a transfer gate, C1 and C2 each denotes a capacitor, BUF1 denotes a buffer circuit, and INV1, INV2, and INV3 each denotes an inverter circuit.

Each of the inverters INV1, INV2, and INV3 is constituted by a circuit in which a p-channel CMOS transistor and an n-channel CMOS Transistor are combined.

For an easy understanding of the general outline of the operation of the comparator 1 shown in FIG. 4, the transistors are described as logical symbols in FIG. 5.

Now, the operation of the comparator 1 will be detailed with reference to FIG. 5. In FIG. 5, the position right in front of the capacitor C1 is denoted as “n1,” the position right in front of the INV1 is denoted as “n2,” the position right behind the INV1 is denoted as “n3,” the position in front of the INV2 is denoted as “n4,” and the position right behind the INV2 is denoted as “n5.”

Initially, TG1, TG3, and TG4 are turned on, and TG2 is turned off. At this time, the analog input voltage AIN is applied to the capacitor C1. The voltage level Vain of this analog input voltage AIN becomes equal to the voltage level Vn1 of the position n1 shown in FIG. 5.

For more easy understanding of the operation of the comparator 1 in the aforementioned status, a simplified block diagram in which TG1, TG2, TG3, and TG4 are omitted is shown in FIG. 6.

When TG3 and TG4 are turned on, a loopback pathway is formed in the vicinity of each of INV1 and INV2. A typical inverter tries to keep the potential of the input stage and that of the output stage around a voltage called VT-star (Vt*).

Accordingly, the potential of the position n2 and that of the position n3 become nearly equal to the voltage Va called VT-star (VT*). FIG. 7 shows the potential called “VT-star (VT*).” When the input and the output are short-circuited, a bias is established at the point “a” in FIG. 7. This point “a” is the highest gain point which is a generally half of the power supply voltage (VCC). The potential of this point “a” is represented as Va. When the potential of the point n2 is represented as Vn2 and the potential of the point n3 is represented as Vn3, Vn2 and Vn3 become equal to Va. In the same manner, Vn4 and Vn5 become equal to Va.

As mentioned above, the potential of the point n1 is Vain and the potential of the point n2 is Va, the potential Vc1 stored in the capacitor C1 is calculated by subtracting Va from Vain. The aforementioned potentials Vn1, Vn2, Vn3 and Vc1 can be represented by the following equations (1) to (4).
Vn1=Vain (1)
Vn2=Vn3=Va (2)
Vn3=Vn4=Va (3)
Vc1=Vain=Va (4)

Thereafter, TG1, TG3, and TG4 are turned off, and TG2 is turned on. Then, the potential of the point n1 becomes Vdac by incorporating Vdac which is a reference voltage from the 8 bits DAC 2 shown in FIG. 1 from the DAOUT terminal. At this time, the potential of the point n2 becomes a value obtained by subtracting the potential (Vain−Va) stored in the capacitor C1 from the potential of the point n1. Accordingly, the potential Vn2 can be represented by the value obtained by subtracting Vain from Vdac and adding Va. The potentials at this time can be represented by the following equations.
Vn1=Vdac (5)
Vn2=Vdac−(Vain−Va)=(Vdac−Vain)+Va (6)

From the above equation (6), if Vdac is larger than Vain, the potential of the point n2, i.e., Vn2, becomes higher than the threshold voltage, and therefore the inverter circuit INV1 outputs an “L” level signal. To the contrary, if Vdac is lower than Vain, the potential of the point n2, i.e., Vn2, becomes lower than the threshold voltage, and therefore the inverter circuit INV1 outputs an “H” level signal.

As to the capacitor C2 and the inverter circuit INV2, as a result of the inverter circuit INV1, they operate as an amplifier for amplifying the potential difference between the reference voltage Vdac and the analog input voltage Vain. The amplified potential difference makes it easy to discriminate whether the output signal is an “H” level or an “L” level.

Furthermore, due to the amplification of the potential difference, the potential at the input stage of the inverter circuit INV1 which was near the threshold voltage becomes a potential near the power supply voltage level or the ground level at the input stage of the inverter circuit INV3. Since the input potential becomes the power supply level potential or the ground level potential, the output voltage of the inverter circuit INV3 also becomes nearly the same level as the power supply voltage level in the case of an “H” level, and becomes nearly the same level as the ground level in the case of an “L” level. Thus, the discrimination between an “H” level and an “L” level can be performed assuredly.

The output signal of the inverter circuit INV3 is inputted to the buffer circuit BUF1 for the waveform shaping, and then the waveform shaped signal is outputted from the output terminal of the buffer circuit BUF1 as a result.

By repeating the aforementioned comparison operation eight times, the analog input voltage AIN will be converted into an 8 bits digital value. The obtained 8 bits digital value will be outputted from the successive approximation logical circuit 3 as an digital output DOUT (see, e.g., Japanese Unexamined Laid-open Patent Publication No. 2004-7131).

According to the circuit structure of a conventional chopper type comparator as shown in FIG. 4, in the case of attaining a low voltage operation by a wide range operation power supply, it is required to lower the threshold voltage of the transistor constituting the comparator. However, simply lowering the threshold voltage of the transistor constituting the comparator tends to cause generation of off-leak current and increase the power consumption in a standby mode.

The description herein of advantages and disadvantages of various features, embodiments, methods, and apparatus disclosed in other publications is in no way intended to limit the present invention. For example, certain features of the preferred embodiments of the invention may be capable of overcoming certain disadvantages and/or providing certain advantages, such as, e.g., disadvantages and/or advantages discussed herein, while retaining some or all of the features, embodiments, methods, and apparatus disclosed therein.

### SUMMARY OF THE INVENTION

The preferred embodiments of the present invention have been developed in view of the above-mentioned and/or other problems in the related art. The preferred embodiments of the present invention can significantly improve upon existing methods and/or apparatuses.

Among other potential advantages, some embodiments can provide a chopper type comparator capable of operating at a low power source voltage VDD.

Among other potential advantages, some embodiments can provide a chopper type comparator capable of reducing the power consumption by decreasing off-leak current in a standby mode.

According to some embodiments of the present invention, a chopper type comparator for comparing an analog voltage to be measured and a reference voltage by sampling and outputting an “H” level signal or an “L” level signal depending on the comparison result, comprising:

a capacitor configured to store a potential difference between the analog voltage and the reference voltage; and

an inverter configured to receive an output signal from the capacitor,

wherein the inverter includes a first p-channel transistor with a threshold voltage lower than a normal threshold voltage, a second p-channel transistor with a normal threshold voltage, a first n-channel transistor with a normal threshold voltage, and a second n-channel transistor with a threshold voltage lower than a normal threshold voltage, and

wherein the second p-channel transistor is turned off by a standby signal and the first n-channel transistor is turned off by an inversion signal of the standby signal to thereby decrease leakage current of the inverter in a standby mode.

With this comparator, even if the comparator is operated by a low power supply voltage, the consumption power can be decreased using the standby signal. Since the off-leak current in the standby mode can be decreased, it becomes possible to operate for a long time with a buttery, e.g., in a portable manner.

In some examples, a source of the first p-channel type transistor is connected to a power supply voltage, a drain of the first p-channel type transistor is connected to a source of the second p-channel type transistor, a drain of the second p-channel type transistor is connected to a source of the first n-channel type transistor, a drain of the first n-channel type transistor is connected to a source of the second n-channel type transistor, and a drain of the second n-channel type transistor is connected to a ground potential.

In the aforementioned comparator, it is preferable that the output signal from the capacitor is inputted into a gate of the first p-channel transistor and a gate of the second n-channel transistor, the standby signal is inputted into a gate of the first n-channel transistor, and an inversion signal of the standby signal is inputted into the second p-channel transistor.

It is also preferable that each of the first p-channel transistor, the second p-channel transistor, the first n-channel transistor, and the second n-channel transistor is a CMOS transistor.

In some examples, it can be configured such that a source of the second p-channel type transistor is connected to a power supply voltage, a drain of the second p-channel type transistor is connected to a source of the first p-channel type transistor, a drain of the first p-channel type transistor is connected to a source of the second n-channel type transistor, a drain of the second n-channel type transistor is connected to a source of the first n-channel type transistor, and a drain of the first n-channel type transistor is connected to a ground potential.

In the aforementioned comparator, it is preferable that the output signal from the capacitor is inputted into a gate of the first p-channel transistor and a gate of the second n-channel transistor, the standby signal is inputted into a gate of the first n-channel transistor, and an inversion signal of the standby signal is inputted into the second p-channel transistor.

It is also preferable that each of the first p-channel transistor, the second p-channel transistor, the first n-channel transistor, and the second n-channel transistor is a CMOS transistor.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF THE DRAWINGS

The preferred embodiments of the present invention are shown by way of example, and not limitation, in the accompanying figures, in which:

FIG. 1 is a block diagram showing a successive approximation type A/D converter including a chopper type comparator;

FIG. 2 is a block diagram showing a chopper type comparator according to an embodiment of the present invention;

FIG. 3 is a block diagram showing a chopper type comparator according to another embodiment of the present invention;

FIG. 4 is a block diagram showing a conventional chopper type comparator;

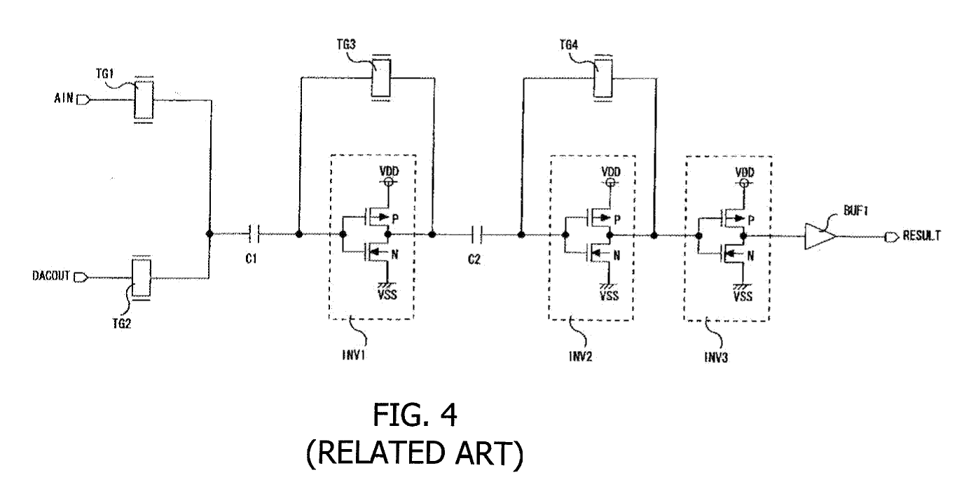

FIG. 5 is a simplified block diagram of the conventional chopper type comparator;

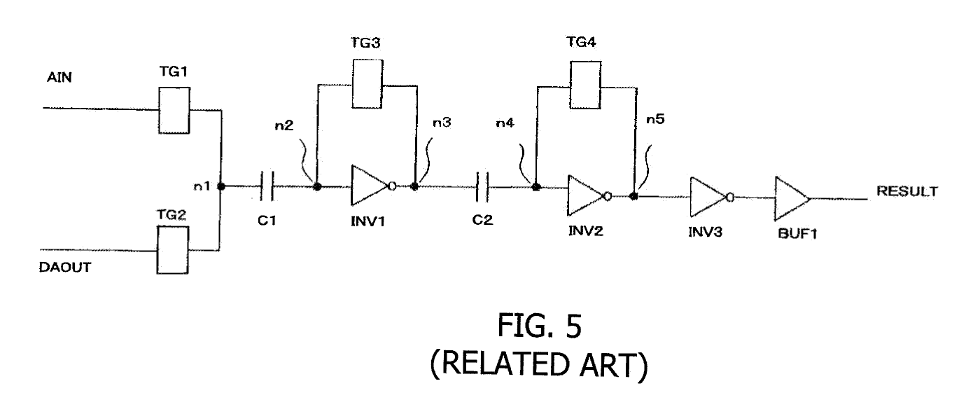

FIG. 6 is a more simplified block diagram of the conventional chopper type comparator; and

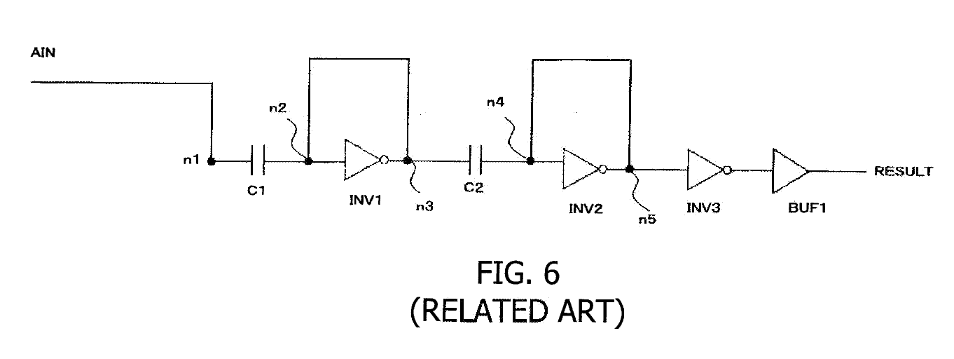

FIG. 7 shows a VT-star (VT*) potential.

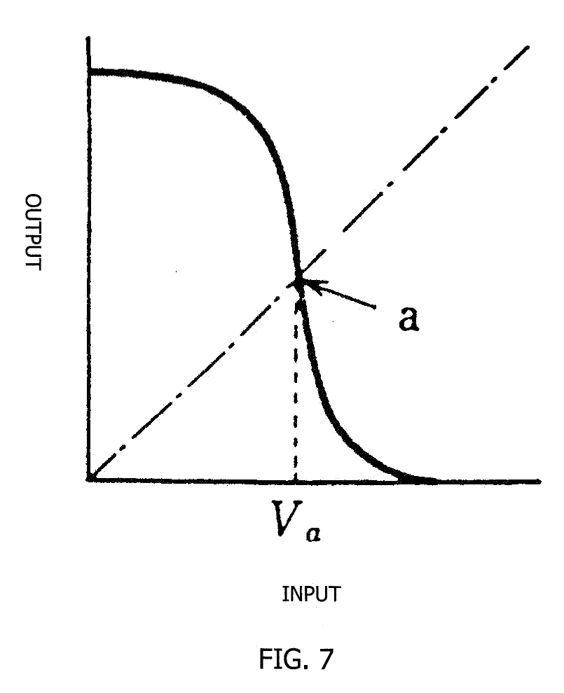

### DETAILED DESCRIPTION OF THE PREFERRED EMBODIMENTS

In the following paragraphs, some preferred embodiments of the invention will be described by way of example and not limitation. It should be understood based on this disclosure that various other modifications can be made by those in the art based on these illustrated embodiments.

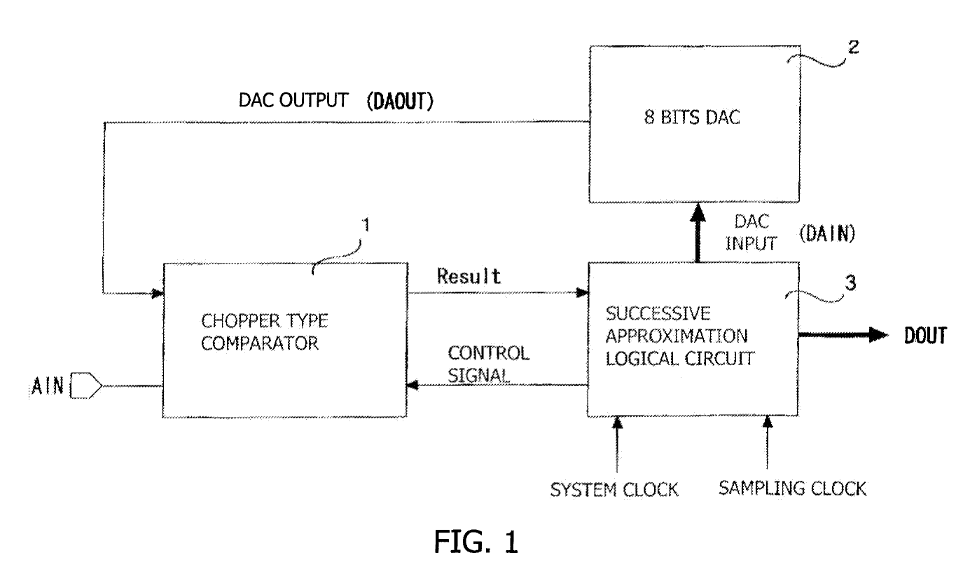

A preferable embodiment of the present invention will be explained with reference to the attached drawings. The following explanation will be directed to a chopper type comparator for preferably use in a successive approximation type A/D converter as shown in FIG. 1. However, it should be understood that the present invention is not limited to the above and can also be applied to various chopper type comparators including, e.g., a comparator required to discriminate of an “H” level and an “L” level of an inputted signal even at a low voltage operation while decreasing power consumption.

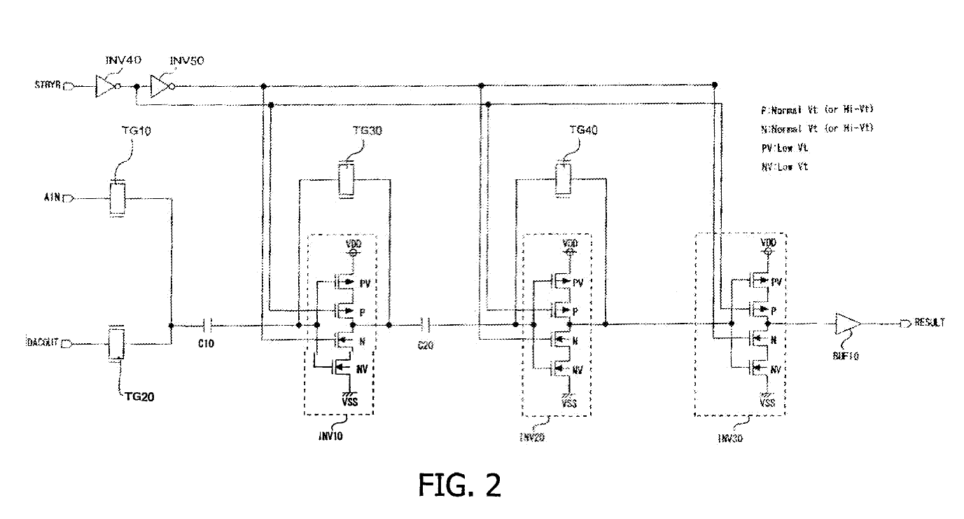

FIG. 2 shows a block diagram showing a chopper type comparator for use in a successive approximation type A/D converter as shown in FIG. 1.

In FIG. 2, TG10, TG20, TG30, and TG40 each denote a transfer gate, C10 and C20 each denote a capacitor, BUF10 denotes a buffer circuit, INV10, INV20, and INV30 each denotes an inverter circuit.

In the chopper type comparator shown in FIG. 2, the steps for sample-holding the analog input voltage AIN and obtaining the digital value sequentially are the same as those explained at the chapter of Description Of the Related Art, and therefore the cumulative explanation will be omitted in the following explanation.

Each of the inverters INV10, INV20 and INV30 constituting the chopper type comparator of this embodiment is constituted by CMOS Transistors. Each inverter INV10, INV20 and INV30 includes a combination of four transistors, i.e., a p-channel transistor PV with a threshold voltage lower than a normal threshold voltage, a p-channel transistor P with a normal threshold voltage, an n-channel transistor N with a normal threshold voltage, and an n-channel transistor NV with a threshold voltage lower than a normal threshold voltage.

The input signal from the capacitor C10 is applied to the p-channel transistor with a threshold voltage lower than a normal threshold voltage and the n-channel transistor NV with a threshold voltage lower than a normal threshold voltage. Because of the low threshold voltage, even if the power supply voltage VDD to be applied to the inverters INV10, INV20 and INV30 becomes lower than a normal voltage, the discrimination of an “H” level and an “L” level of an inputted signal can be performed without problems. For example, in cases where a normal power supply voltage is 5V and the threshold voltage is 2.5V, when only the power supply voltage is simply decreased to 3V, since no threshold voltage changes, it becomes difficult to discrimination whether the inputted signal is an “H” level or an “L” level.

In FIG. 2, STABYB denotes a standby signal. This standby signal will be used to bring the inverters INV10, INV20 and INV30 constituting the chopper type comparator 1 into a standby mode. The standby signal is in an “H” level in a normal operation mode and in an “L” level in a standby mode. In this embodiment, in a standby mode, it is configured such that an “H” level STBYB signal is applied to the normal threshold voltage p-channel transistors P of the inverters INV10, INV20 and INV30 and an “L” level STABY signal is applied to the normal threshold voltage n-channel transistors N of the inverters INV10, INV20 and INV30. In this embodiment, in an standby active mode, it is configured to apply an “H” level signal to the normal threshold voltage p-channel transistors P and an “L” level signal to the normal threshold voltage n-channel transistors N using the inverters INV40 and INV50.

In a standby mode, the normal threshold voltage p-channel transistor P is turned off when the input is an “H” level and the normal threshold voltage n-channel transistor N is turned off when the input is an “L” level. In the off-status, the normal p-channel transistor P and the normal n-channel transistor N become extremely large in resistance, resulting in no leakage current flow. As a result, it becomes possible to prevent an occurrence of a large leakage current flow in a standby mode.

As will be apparent from the above, in this embodiment, in cases where the chopper type comparator is not used for a relatively long time period, the consumption current can be decreased by setting the STBYB signal to an “L” level.

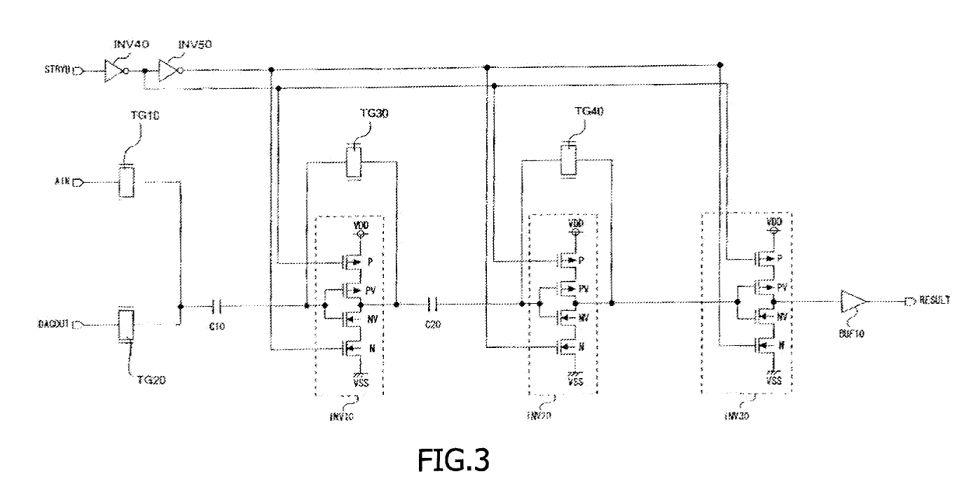

In each structure of the inverters INV10, INV20 and INV30 shown in FIG. 2, a p-channel transistor PV with a threshold voltage lower than a normal threshold voltage, a p-channel transistor P with a normal threshold voltage, an n-channel transistor N with a normal threshold voltage, and an n-channel transistor NV with a threshold voltage lower than a normal threshold voltage are arranged in this order from the top. In place of this order, it can be configured such that a p-channel transistor P with a normal threshold voltage, a p-channel transistor PV with a threshold voltage lower than a normal threshold voltage, an n-channel transistor NV with a threshold voltage lower than a normal threshold voltage and an n-channel transistor N with a normal threshold voltage can be arranged in this order from the top as shown in FIG. 3.

As shown in FIG. 3, in this alternative embodiment, in the same manner as in the embodiment shown in FIG. 2, the input signal from the capacitor C10 is inputted into the p-channel transistor PV with a threshold voltage lower than a normal threshold voltage and the n-channel transistor NV with a threshold voltage lower than a normal threshold voltage. The STBYB signal is inputted into the normal p-channel transistors P and the normal n-channel transistors N of the invertors INV10, INV20 and INV30. The other structure is is the same as that of the embodiment shown in FIG. 2, and therefore the corresponding reference numeral is allotted to the corresponding portion to omit the explanation.

In the aforementioned embodiments of the present invention, even if the applying power supply voltage VDD is low, the comparator can be operated. Even if the comparator is operated at a low power supply voltage, the consumption power can be decreased using a standby signal. Since off-leak current in a standby mode can be decreased, it becomes possible to operate for a long time with a buttery, e.g., in a portable manner.

While the present invention may be embodied in many different forms, a number of illustrative embodiments are described herein with the understanding that the present disclosure is to be considered as providing examples of the principles of the invention and such examples are not intended to limit the invention to preferred embodiments described herein and/or illustrated herein.

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims are to be interpreted broadly based on the language employed in the claims and riot limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” is meant as a non-specific, general reference and may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure and during the prosecution of this case, the following abbreviated terminology may be employed: “e.g.” which means “for example;” and “NB” which means “note well.”

What is claimed is:

1. A chopper type comparator for comparing an analog voltage to be measured and a reference voltage by sampling and outputting an “H” level signal or an “L” level signal depending on the comparison result, comprising:
a capacitor configured to store a potential difference between the analog voltage and the reference voltage; and
an inverter configured to receive an output signal from the capacitor,
wherein the inverter includes a first p-channel transistor with a threshold voltage lower than a normal threshold voltage, a second p-channel transistor with a normal threshold voltage, a first n-channel transistor with a normal threshold voltage, and a second n-channel transistor with a threshold voltage lower than a normal threshold voltage, and
wherein the second p-channel transistor is turned off by a standby signal and the first n-channel transistor is turned off by an inversion signal of the standby signal to thereby decrease leakage current of the inverter in a standby mode.

2. The chopper type comparator as recited in claim 1, wherein a source of the first p-channel type transistor is connected to a power supply voltage, a drain of the first p-channel type transistor is connected to a source of the second p-channel type transistor, a drain of the second p-channel type transistor is connected to a source of the first n-channel type transistor, a drain of the first n-channel type transistor is connected to a source of the second n-channel type transistor, and a drain of the second n-channel type transistor is connected to a ground potential.

3. The chopper type comparator as recited in claim 1, wherein the output signal from the capacitor is inputted into a gate of the first p-channel transistor and a gate of the second n-channel transistor, the standby signal is inputted into a gate of the first n-channel transistor, and an inversion signal of the standby signal is inputted into the second p-channel transistor.

4. The chopper type comparator as recited in claim 2, wherein the output signal from the capacitor is inputted into a gate of the first p-channel transistor and a gate of the second n-channel transistor, the standby signal is inputted into a gate of the first n-channel transistor, and an inversion signal of the standby signal is inputted into the second p-channel transistor.

5. The chopper type comparator as recited in claim 1, wherein each of the first p-channel transistor, the second p-channel transistor, the first n-channel transistor, and the second n-channel transistor is a CMOS transistor.

6. The chopper type comparator as recited in claim 2, wherein each of the first p-channel transistor, the second p-channel transistor, the first n-channel transistor, and the second n-channel transistor is a CMOS transistor.

7. The chopper type comparator as recited in claim 3, wherein each of the first p-channel transistor, the second p-channel transistor, the first n-channel transistor, and the second n-channel transistor is a CMOS transistor.

8. The chopper type comparator as recited in claim 4, wherein each of the first p-channel transistor, the second p-channel transistor, the first n-channel transistor, and the second n-channel transistor is a CMOS transistor.

9. The chopper type comparator as recited in claim 1, wherein a source of the second p-channel type transistor is connected to a power supply voltage, a drain of the second p-channel type transistor is connected to a source of the first p-channel type transistor, a drain of the first p-channel type transistor is connected to a source of the second n-channel type transistor, a drain of the second n-channel type transistor is connected to a source of the first n-channel type transistor, and a drain of the first n-channel type transistor is connected to a ground potential.

10. The chopper type comparator as recited in claim 9, wherein the output signal from the capacitor is inputted into a gate of the first p-channel transistor and a gate of the second n-channel transistor, the standby signal is inputted into a gate of the first n-channel transistor, and an inversion signal of the standby signal is inputted into the second p-channel transistor.

11. The chopper type comparator as recited in claim 9, wherein each of the first p-channel transistor, the second p-channel transistor, the first n-channel transistor, and the second n-channel transistor is a CMOS transistor.

12. The chopper type comparator as recited in claim 9, wherein each of the first p-channel transistor, the second p-channel transistor, the first n-channel transistor, and the second n-channel transistor is a CMOS transistor.
